(19) United States
(12) Patent Application Publication
(10) Pub. No.: US 2025/0059679 A1
(43) Pub. Date: Feb. 20, 2025

(54) SiC EPITAXIAL WAFER AND MANUFACTURING METHOD OF SiC EPITAXIAL WAFER

(71) Applicant: Resonac Corporation, Tokyo (JP)

(72) Inventors: Marusu KATADA, Tokyo (JP); Naoto ISHIBASHI, Tokyo (JP)

(73) Assignee: Resonac Corporation, Tokyo (JP)

(21) Appl. No.: 18/799,560

(22) Filed: Aug. 9, 2024

(30) Foreign Application Priority Data
Aug. 14, 2023 (JP) 2023-131874

(51) Int. Cl. C30B 29/36; C30B 25/12; C30B 25/14; H01L 21/02; H01L 29/16

(52) U.S. Cl. CPC C30B 29/36; C30B 25/12; C30B 25/14; H01L 21/02378; H01L 21/02529; H01L 21/02634; H01L 29/1608

(57) ABSTRACT

A SiC epitaxial wafer (1) of the present invention is a SiC epitaxial wafer having a SiC epitaxial film (E) on a main surface of a SiC single crystal substrate (W), in which an orientation flat or a notch is provided thereon, a height (h) of an epi crown (Ec), which is present on an outer circumferential portion of the SiC epitaxial film, with respect to a level surface of the SiC epitaxial film (E) at a position on a wafer diameter intersecting a longitudinal center of the orientation flat or a groove bottom of the notch is 30% or less of a thickness (Et) of the SiC epitaxial film (E) at a wafer center (C), and the SiC epitaxial film (E) does not have triangular defects in a region less than 1 mm from an edge in a direction toward the wafer center.

### BACKGROUND OF THE INVENTION

### Field of the Invention

The present invention relates to a SiC epitaxial wafer and a manufacturing method of a SiC epitaxial wafer.

Priority is claimed on Japanese Patent Application No. 2023-131874 filed on Aug. 14, 2023, the content of which is incorporated herein by reference.

### Description of Related Art

Conventionally, epitaxial wafers are used in manufacturing semiconductor devices. Silicon carbide (SiC) has a dielectric breakdown electric field strength ten times larger and a band gap three times larger compared to silicon (Si). Also, silicon carbide (SiC) has a thermal conductivity about three times higher compared to silicon (Si). Due to this, SiC epitaxial wafers have been used for semiconductor devices such as power devices, high frequency devices, and high-temperature operation devices. Also, in recent years, SiC epitaxial wafers have been enlarged in diameter to improve the production efficiency of devices.

Normally, a SiC epitaxial wafer is manufactured by a method of forming a SiC epitaxial film, which will serve as an active region of a SiC power semiconductor device, on a SiC single crystal substrate using a chemical vapor deposition (CVD) method.

Patent Document 1 describes a silicon carbide epitaxial substrate including a silicon carbide single crystal substrate having a first main surface, and a silicon carbide layer on the first main surface, in which the silicon carbide layer includes a second main surface on a side opposite to a surface in contact with the silicon carbide single crystal substrate, and the second main surface has an outer circumferential region within 3 mm from an outer edge of the second main surface, and a central region surrounded by the outer circumferential region. Also, Patent Document 1 describes that, when the central region is divided into square regions with a side length of 6 mm, a proportion of the number of the square regions having at least one of downfall defects and triangular defects with respect to the number of all the square regions is 10% or less. Also, in FIGS. 54 and 55 of Patent Document 1, maps showing an in-plane distribution of triangular defects on the second main surfaces of samples 7 and 9 are shown. Table 3 of Patent Document 1 shows that a substrate diameter of samples 7 and 9 is 150 mm, and paragraph (0180) describes that an area of a region in which defects are measured is about 170 cm².

Patent Document 2 describes a SiC epitaxial wafer in which the number of end portion defects, which is measured along an outer circumference over half the circumference of the wafer on a starting point side of step-flow growth in a region up to 1 mm from an outer circumferential end portion of a SiC single crystal substrate on the starting point side of the step-flow growth, divided by a length of an outer circumference of the wafer is within 30 defects/m, and the end portion defects are observed as irregularities, which have a shape in which a flat surface different from the surrounding surfaces exists in a straight line, in the outer circumferential end portion on the starting point side of the step-flow growth. Also, Patent Document 2 describes that the end portion defect has a crack-like shape as illustrated in FIG. 5 of Patent Document 2.

Patent Document 3 describes a wafer support base including a wafer placement surface on which a substrate is placed on an upper surface thereof and a wafer support part that stands upright to surround a circumference of the placed wafer, in which a height from a portion of an upper surface of the wafer support part on a reaction space side that is farthest from the wafer placement surface to a main surface of the wafer placed on the wafer placement surface is 1 mm or more. Patent Document 3 describes an epitaxial wafer having an epitaxial film on the main surface of the wafer formed using a chemical vapor deposition apparatus having the wafer support base, in which a height of an epi crown of the epitaxial film formed on a wafer circumferential portion with respect to a level surface of the epitaxial film is within 30% of a thickness of the epitaxial film at a wafer center.

### PATENT DOCUMENTS

[Patent Document 1] Japanese Patent No. 6969628

[Patent Document 2] Japanese Patent No. 6481790

[Patent Document 3] Japanese Unexamined Patent Application, First Publication No. 2016-111043

### SUMMARY OF THE INVENTION

At an outer circumferential portion of a SiC epitaxial wafer, there is an edge exclusion which is expressed as a distance from an edge thereof. An area outside the edge exclusion is a region of inferior performance and is an invalid region that is not used for products such as devices. Therefore, the outward side of the edge exclusion is generally not subject to inspection when the SiC epitaxial wafer is evaluated.

In recent years, there has been a demand to reduce the area outside the edge exclusion to increase an effective area in SiC epitaxial wafers. The effect of reducing the area outside the edge exclusion to increase the effective area becomes more pronounced as a diameter of the SiC epitaxial wafer increases. Therefore, there has been a strong demand for reducing the edge exclusion in large-diameter SiC epitaxial wafers.

Also, typically, when a SiC epitaxial film is grown on a SiC single crystal substrate by a chemical vapor deposition (CVD) method, a substantially annular epi crown formed of the SiC epitaxial film that is thicker than a central portion is formed on an outer circumferential portion due to a difference in crystal growth rate between the central portion and the outer circumferential portion. The epi crown may break during transportation of the SiC epitaxial wafer to cause damage to a surface, or cause cracks during processing of the SiC epitaxial wafer. Therefore, a SiC epitaxial wafer in which a difference between a thickness of the SiC epitaxial film forming the epi crown and a thickness of the central portion of the SiC epitaxial film is small is desired.

The epi crown may be removed by polishing the SiC epitaxial wafer after the SiC epitaxial film is grown. However, polishing the SiC epitaxial wafer to remove the epi crown may cause the SiC epitaxial wafer to crack, resulting in reduced yield. Also, if a SiC epitaxial film is grown on a SiC single crystal substrate, the SiC epitaxial film is very hard, making it difficult to remove the epi crown by polishing. Particularly, in a case of a large-diameter SiC epitaxial wafer, it is difficult to remove the epi crown by polishing.

Also, even if the epi crown can be removed by polishing, there is a disadvantage in that the SiC epitaxial film in a region in which the epi crown has existed and its vicinity may be deteriorated due to damage caused by polishing. As a result, the region in which the epi crown has been removed and its vicinity become an invalid region that is not used for products such as devices. Therefore, the SiC epitaxial wafer from which the epi crown has been removed by polishing could not be made with a small edge exclusion.

Also, as a method of suppressing growth of the epi crown when the SiC epitaxial film is grown, it is conceivable to use a method of manufacturing the SiC epitaxial wafer by supplying a gas containing a source gas onto a SiC single crystal substrate from the outside of an outer circumferential end portion of the SiC single crystal substrate using a chemical vapor deposition apparatus which includes a wafer support base having a wafer placement surface on which the SiC single crystal substrate is placed on an upper surface thereof, and a wafer support part standing upright to surround a circumference of the SiC single crystal substrate, and in which a height from a portion of an upper surface of the wafer support part on a reaction space side that is farthest from the wafer placement surface to a main surface of the SiC single crystal substrate placed on the wafer placement surface is 1 mm or more.

In this method, since the wafer support part appropriately hinders supply of the source gas to the outer circumferential portion of the SiC single crystal substrate, a growth rate of the SiC epitaxial film in the outer circumferential portion is suppressed, and the growth of the epi crown is suppressed. However, the SiC epitaxial wafer manufactured using a chemical vapor deposition apparatus having the above-described wafer support base has triangular defects that are present on the outer edge portion of the SiC epitaxial film formed on the SiC single crystal substrate, and therefore cracks are likely to occur during processing of the SiC epitaxial wafer.

The present invention has been made in consideration of the above-described circumstances, and an objective of the present invention is to provide a SiC epitaxial wafer having a SiC epitaxial film in which growth of an epi crown is suppressed, having no triangular defects present in an outer edge portion of the SiC epitaxial film, and being less likely to crack during processing of the SiC epitaxial wafer, and a manufacturing method thereof.

In order to solve the above problems and realize a SiC epitaxial wafer having a SiC epitaxial film in which growth of the epi crown is suppressed and triangular defects are not present in an outer edge portion, the present inventors have conducted extensive research as described below. First, the present inventors have investigated the cause of triangular defects being formed on the outer edge portion of the SiC epitaxial film when the SiC epitaxial film is formed by supplying a gas containing a source gas onto a SiC single crystal substrate from the outside of an outer circumferential end portion of the SiC single crystal substrate using a chemical vapor deposition apparatus which includes a wafer support base having a wafer placement surface on which the SiC single crystal substrate is placed on an upper surface thereof, and a wafer support part standing upright to surround a circumference of the SiC single crystal substrate, and in which a height from a portion of an upper surface of the wafer support part on a reaction space side that is farthest from the wafer placement surface to a main surface of the SiC single crystal substrate placed on the wafer placement surface is 1 mm or more as a method of suppressing growth of the epi crown when the SiC epitaxial film is grown.

As a result, it was found that, when the SiC epitaxial film is formed, a side surface of the SiC single crystal substrate and an annular wall surface of the wafer support part standing upright to surround it rub against each other and generate dust due to deformation of the SiC single crystal substrate according to a rise in temperature of the SiC single crystal substrate, causing the dust to adhere to the SiC epitaxial film.

Therefore, for example, if a wafer support base formed only of the wafer placement surface without the wafer support part is used, and a SiC epitaxial film is grown on the SiC single crystal substrate by placing the entirety of a surface of the SiC single crystal substrate on a side opposite to the main surface to be in contact with the wafer placement surface, triangular defects caused by dust generation due to rubbing between the side surface of the SiC single crystal substrate and the wafer support part will not be formed. In this case, however, since a growth rate of the SiC epitaxial film in the outer circumferential portion is not suppressed, growth of the epi crown in the outer circumferential portion of the SiC epitaxial film cannot be suppressed. Also, in a step of growing the SiC epitaxial film, the SiC single crystal substrate may move onto the wafer placement surface, the surface of the SiC single crystal substrate on a side opposite to the main surface and the wafer placement surface may rub against each other and generate dust, and triangular defects may be formed.

Therefore, the present inventors focused on disposition of the wafer support part and the SiC single crystal substrate described above, and conducted further studies. Typically, when a SiC epitaxial film is grown on a SiC single crystal substrate by a chemical vapor deposition (CVD) method, the entirety of a surface of the SiC single crystal substrate on a side opposite to the main surface is disposed in contact with the flat wafer placement surface of the wafer support base. It has been common knowledge for engineers in this field to stably rotate the SiC single crystal substrate together with the wafer support base, prevent disturbance in a flow of the source gas on the SiC single crystal substrate, and grow a SiC epitaxial film with a uniform thickness on the main surface of the SiC single crystal substrate.

However, the present inventors considered that it would be sufficient to, by using a wafer support base having the above-described wafer support part, place the main surface of the SiC single crystal substrate having an orientation flat or a notch to be inclined with respect to the wafer placement surface of the wafer support base, and dispose a part of the SiC single crystal substrate on an outward side of the annular wall surface of the wafer support part in a plan view. Then, it has been found that the above-described problem can be solved by moving the SiC single crystal substrate along the annular wall surface of the wafer support part while deforming it by rotating the wafer support base while raising a temperature of the SiC single crystal substrate to accommodate the entire SiC single crystal substrate inside the annular wall surface of the wafer support part before the temperature of the SiC single crystal substrate reaches an epitaxial growth temperature, and grow the SiC epitaxial film.

In this case, even if the SiC single crystal substrate deforms according to a rise in temperature of the SiC single crystal substrate, a region in which the side surface of the SiC single crystal substrate faces the wafer support part is smaller than a case in which, for example, the SiC single crystal substrate is placed inside the annular wall surface of the wafer support part. Therefore, the side surface of the SiC single crystal substrate rubbing against the wafer support part can be suppressed. Also, movement of the SiC single crystal substrate on the wafer placement surface during growth of the SiC epitaxial film is suppressed by the wafer support part. Therefore, triangular defects caused by dust generation due to rubbing between the SiC single crystal substrate and the wafer support part and/or the wafer placement surface can be prevented from being formed in the outer edge portion, and it is possible to obtain a SiC epitaxial film that does not have triangular defects in a region less than 1 mm from an edge in a direction toward a wafer center.

Moreover, deformation of the SiC single crystal substrate according to a rise in temperature of the SiC single crystal substrate causes the entirety of the SiC single crystal substrate to be accommodated inside the annular wall surface of the wafer support part before the temperature of the SiC single crystal substrate reaches the epitaxial growth temperature. Therefore, even if the main surface of the SiC single crystal substrate is placed to be inclined with respect to the wafer placement surface of the wafer support base before the temperature of the SiC single crystal substrate reaches the epitaxial growth temperature, at the time when the growth of the SiC epitaxial film starts, the entirety of the surface of the SiC single crystal substrate on a side opposite to the main surface is disposed to be in contact with the flat wafer placement surface of the wafer support base. Therefore, disturbance in a flow of the source gas does not occur on the SiC single crystal substrate that has reached the epitaxial growth temperature, and a SiC epitaxial film with a uniform thickness can be grown on the main surface of the SiC single crystal substrate.

Also, since the wafer support part appropriately hinders supply of the source gas to the outer circumferential portion of the SiC single crystal substrate that has reached the epitaxial growth temperature, a growth rate of the SiC epitaxial film in the outer circumferential portion is suppressed, and growth of the epi crown is suppressed. Further, the present inventors have confirmed that, if the wafer support part has an annular wall surface having a height dimension larger than a thickness dimension of the SiC single crystal substrate, it is possible to obtain a SiC epitaxial wafer in which the height of the epi crown with respect to a level surface of the SiC epitaxial film at a position on a wafer diameter intersecting a longitudinal center of the orientation flat or a groove bottom of the notch is 30% or less of the thickness of the SiC epitaxial film at the wafer center, and conceived the present invention.

That is, the present invention relates to the following.
[1] A SiC epitaxial wafer according to one aspect of the present invention is a SiC epitaxial wafer, which has a SiC single crystal substrate and a SiC epitaxial film on a main surface of the SiC single crystal substrate, in which an orientation flat or a notch is provided thereon, a height of an epi crown, which is present on an outer circumferential portion of the SiC epitaxial film, with respect to a level surface of the SiC epitaxial film is 30% or less of a thickness of the SiC epitaxial film at a wafer center, the epi crown and the wafer center being at a position on a wafer diameter intersecting a longitudinal center of the orientation flat or a groove bottom of the notch, and the SiC epitaxial film does not have triangular defects in a region less than 1 mm from an edge in a direction toward the wafer center.
[2] In the SiC epitaxial wafer according to the above-described [1], the SiC epitaxial film preferably does not have triangular defects in a region of 2 mm to 3 mm from the edge in a direction toward the wafer center.
[3] In the SiC epitaxial wafer according to the above-described [1] or [2], the SiC epitaxial film preferably does not have triangular defects in a region 3 mm or less from the edge in a direction toward the wafer center.
[4] In the SiC epitaxial wafer according to any one of the above-described [1] to [3], a nitrogen concentration of the SiC epitaxial film at a position 1 mm from the edge in a direction toward the wafer center is preferably 108% or less of a nitrogen concentration thereof at the wafer center.
[5] A manufacturing method of a SiC epitaxial wafer according to one aspect of the present invention is a manufacturing method of a SiC epitaxial wafer by which a SiC epitaxial film is grown on a main surface of a SiC single crystal substrate, comprising: a film deposition step of growing the SiC epitaxial film by a chemical vapor deposition method using a chemical vapor deposition apparatus which includes a wafer support base, the wafer support base having a wafer placement surface on which the SiC single crystal substrate is placed, and a wafer support part, the wafer support part having an annular wall surface standing upright to surround a circumference of the SiC single crystal substrate, and the height dimension of the annular wall surface is larger than a thickness dimension of the SiC single crystal substrate, wherein the film deposition step includes: a substrate placement step in which the SiC single crystal substrate is placed so that the main surface thereof is inclined with respect to the wafer placement surface, and a part of the SiC single crystal substrate is disposed outward of the annular wall surface of the wafer support part in a plan view; and an epitaxial growth step in which the entirety of the SiC single crystal substrate is accommodated inside the annular wall surface of the wafer support part before a temperature of the SiC single crystal substrate reaches an epitaxial growth temperature by rotating the wafer support base while raising the temperature of the SiC single crystal substrate, and a gas containing a source gas is supplied onto the SiC single crystal substrate from the outside of an outer circumferential end portion of the SiC single crystal substrate.
[6] In the manufacturing method of a SiC epitaxial wafer according to the above-described [5], an orientation flat of the SiC single crystal substrate may be placed outward of the annular wall surface of the wafer support part.
[7] In the manufacturing method of a SiC epitaxial wafer according to the above-described [5] or [6], an area of a surface of the SiC single crystal substrate on a side opposite to the main surface, which is placed outward of the annular wall surface of the wafer support part in a plan view, is preferably 0.01% to 10% of an area of the SiC single crystal substrate.
[8] In the manufacturing method of a SiC epitaxial wafer according to any one of the above-described [5] to [7], the wafer support base in which at least a part of one or both of a surface of the wafer placement surface facing the SiC single crystal substrate and a surface of the wafer support part is made of graphite may be used, and a nitrogen-containing gas, together with a source gas containing silane and propane, may be supplied onto the SiC single crystal substrate.

The SiC epitaxial wafer of the present invention is a SiC epitaxial wafer having a SiC epitaxial film on a main surface of a SiC single crystal substrate, in which an orientation flat or a notch is provided thereon, a height of an epi crown, which is present on an outer circumferential portion of the SiC epitaxial film, with respect to a level surface of the SiC epitaxial film at a position on a wafer diameter intersecting a longitudinal center of the orientation flat or a groove bottom of the notch is 30% or less of a thickness of the SiC epitaxial film at a wafer center, and the SiC epitaxial film does not have triangular defects in a region less than 1 mm from an edge in a direction toward the wafer center. Therefore, in the SiC epitaxial wafer of the present invention, cracks of the SiC epitaxial wafer due to triangular defects on the outer edge portion of the SiC epitaxial film are less likely to occur during processing.

### BRIEF DESCRIPTION OF THE DRAWINGS

FIG. 1A is a plan view illustrating an example of a SiC epitaxial wafer of the present embodiment.

FIG. 1B is a cross-sectional view of the SiC epitaxial wafer illustrated in FIG. 1A taken along line I-I′.

FIG. 2A is a plan view for illustrating a film deposition step in a manufacturing method of a SiC epitaxial wafer 1 of the present embodiment.

FIG. 2B is a cross-sectional view taken along line II-II′ in FIG. 2A.

### DETAILED DESCRIPTION OF THE INVENTION

Hereinafter, an epitaxial wafer and a manufacturing method of the epitaxial wafer of the present invention will be described in detail with reference to the drawings as appropriate. In the drawings used in the following description, there are cases in which characteristic portions are enlarged for convenience of illustration so that characteristics of the present invention can be easily understood. Therefore, dimensional proportions of respective constituent elements may be different from actual ones. Also, materials, dimensions, and the like illustrated in the following description are merely examples, and the present invention is not limited thereto and can be implemented with appropriate modifications within a range not changing the gist thereof.

### Epitaxial Wafer

An epitaxial wafer of the present embodiment is an epitaxial wafer having an epitaxial film on a main surface of a single crystal substrate in which an orientation flat or a notch is provided. Hereinafter, as an example of the epitaxial wafer of the present embodiment, a case in which the single crystal substrate is a SiC single crystal substrate, the epitaxial film is a SiC epitaxial film, and an orientation flat is provided will be described.

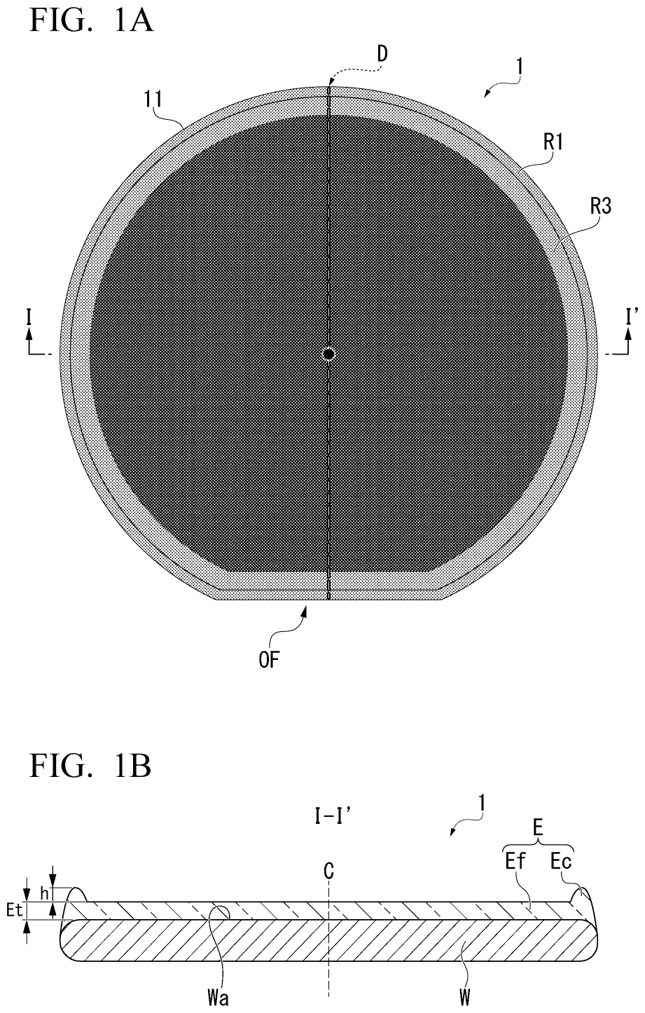

FIG. 1A is a plan view illustrating an example of a SiC epitaxial wafer according to the present embodiment. FIG. 1B is a cross-sectional view of the SiC epitaxial wafer illustrated in FIG. 1A taken along line I-I′.

In FIGS. 1A and 1B, reference sign 1 denotes the SiC epitaxial wafer. As illustrated in FIG. 1B, the SiC epitaxial wafer 1 has a SiC single crystal substrate W and a SiC epitaxial film E formed on a main surface Wa thereof. As illustrated in FIG. 1A, an orientation flat OF is provided in the SiC epitaxial wafer 1 of the present embodiment.

In the present embodiment, the “main surface Wa of the SiC single crystal substrate W” means a flat surface of the SiC single crystal substrate W on a side on which the SiC epitaxial film E is formed.

As illustrated in FIG. 1B, the SiC epitaxial film E has a flat portion Ef and an epi crown Ec that is present on an outer circumferential portion of the SiC epitaxial film E.

The flat portion Ef has a flat surface extending from a wafer center C toward the outer circumferential portion, and has a substantially uniform thickness.

As illustrated in FIG. 1B, the epi crown Ec is formed of the SiC epitaxial film E that is thicker than the flat portion Ef. The epi crown Ec is formed in a substantially annular shape on the outer circumferential portion of the SiC epitaxial film E. In the SiC epitaxial wafer 1 of the present embodiment, a height h of the epi crown Ec, which is present on the outer circumferential portion of the SiC epitaxial film E, with respect to a level surface of the SiC epitaxial film E is 30% or less of a film thickness Et of the SiC epitaxial film E at the wafer center C. The SiC epitaxial film E of the SiC epitaxial wafer 1 of the present embodiment is not one in which the epi crown has been removed by polishing.

In the SiC epitaxial wafer 1 of the present embodiment, since the height h of the epi crown Ec with respect to the level surface of the SiC epitaxial film E is 30% or less of the film thickness Et of the SiC epitaxial film E at the wafer center C, inconvenience caused by having the epi crown Ec is unlikely to occur. The height h described above is preferably smaller, and is preferably 20% or less of the film thickness Et of the SiC epitaxial film E at the wafer center C, more preferably 10% or less, still more preferably 5% or less, particularly preferably 2% or less, and most preferably 0% or less. If the height h is 0% or less, it can be determined that the epi crown Ec is not formed.

In the present embodiment, the “level surface of the SiC epitaxial film E” is an ideal surface formed by the SiC epitaxial film E, and means a surface that is vertically separated from the main surface Wa of the SiC single crystal substrate W by the film thickness Et of the SiC epitaxial film E at the wafer center C. The “height h of the epi crown Ec with respect to the level surface of the SiC epitaxial film E” means, in other words, a length of a vertical line drawn from a top surface or apex of the epi crown Ec to the level surface of the SiC epitaxial film E. Further, if an edge of the SiC single crystal substrate is chamfered, the top surface or apex of the epi crown may be present on a surface of the SiC epitaxial film grown on the chamfered portion. In such a case, a distance from the top surface or apex of the epi crown present on the surface of the SiC epitaxial film grown on the chamfered portion to the level surface of the SiC epitaxial film formed on the SiC single crystal substrate whose edge has been chamfered is defined as a height of the epi crown with respect to the level surface of the SiC epitaxial film.

The film thickness Et of the SiC epitaxial film E and the height h of the epi crown Ec with respect to the level surface of the SiC epitaxial film E can be measured using a cross-sectional image of the SiC epitaxial film E captured using a scanning electron microscope (SEM). Also, the height h of the epi crown Ec with respect to the level surface of the SiC epitaxial film E may be measured by using Fourier transform infrared spectroscopy method (FT-IR method).

In the SiC epitaxial wafer 1 of the present embodiment, the height h of the epi crown Ec with respect to the level surface of the SiC epitaxial film E means the height h measured by the above-described method for the top surface or apex of the epi crown Ec present on the outer circumferential portion of the SiC epitaxial film E at a position on a wafer diameter intersecting a longitudinal center of the orientation flat OF (in other words, at a position on the outer circumferential portion of the SiC epitaxial film E on a side opposite to a position at which the longitudinal center of the orientation flat OF is provided with respect to the wafer center (the position indicated by reference sign D in FIG. 1A)).

The height h of the epi crown Ec with respect to the level surface of the SiC epitaxial film E and a dimensional difference in the height h described above due to a circumferential position of the SiC epitaxial film E are unlikely to be affected by whether or not the orientation flat OF is provided. Therefore, if the SiC epitaxial wafer 1 is one provided with the orientation flat OF, the height h measured by the above-described method for the top surface or apex of the epi crown Ec present on the outer circumferential portion of the SiC epitaxial film E at a position on a wafer diameter intersecting the longitudinal center of the orientation flat OF can be taken as the height h of the epi crown Ec with respect to the level surface of the SiC epitaxial film E.

Specifically, a dimensional difference of the height h due to a measurement position in the circumferential direction of the SiC epitaxial film E is typically 5 μm or less. Therefore, when the height h measured by the above-described method for the top surface or apex of the epi crown Ec of the SiC epitaxial film E at the position on a wafer diameter intersecting the longitudinal center of the orientation flat OF is 30% or less of the film thickness Et of the SiC epitaxial film E at the wafer center C, it can be said that the SiC epitaxial film E is one in which growth of the epi crown Ec has been sufficiently suppressed.

If the SiC epitaxial wafer 1 is one provided with the orientation flat OF, positions on an upstream side and a downstream side of a step flow in the outer circumferential portion of the SiC epitaxial film E are preferably positions on the diameter of the SiC epitaxial film E in a direction in which the orientation flat OF extends.

In the SiC epitaxial wafer 1 of the present embodiment, not only the height h at the position on a wafer diameter intersecting the longitudinal center of the orientation flat OF, but also a maximum value h2 of the height of the epi crown Ec with respect to the level surface of the SiC epitaxial film E measured by the above-described method for each of two locations on the upstream side and the downstream side of the step flow in the outer circumferential portion of the SiC epitaxial film E is preferably 30% or less of the film thickness Et of the SiC epitaxial film E at the wafer center C.

Further, in the SiC epitaxial wafer 1, a maximum value h3 of the height of the epi crown Ec with respect to the level surface of the SiC epitaxial film E measured by the above-described method for each of eight locations disposed along the outer circumferential portion at substantially regular intervals including the position on a wafer diameter intersecting the longitudinal center of the orientation flat OF and the two locations on the upstream side and the downstream side of the step flow in the outer circumferential portion of the SiC epitaxial film E is preferably 30% or less of the film thickness Et of the SiC epitaxial film E at the wafer center C.

The maximum value h2 and the maximum value h3 described above are preferably smaller, and are more preferably 20% or less of the film thickness Et of the SiC epitaxial film E at the wafer center C, still more preferably 10% or less, yet still more preferably 5% or less, particularly preferably 2% or less, and most preferably 0% or less (no epi crown Ec is formed).

Also, if the SiC epitaxial wafer 1 is one provided with the orientation flat OF, not only the height h at the position on a wafer diameter intersecting the longitudinal center of the orientation flat OF, but also a height h4 of the epi crown Ec with respect to the level surface of the SiC epitaxial film E measured by the above-described method for arbitrary one location of a portion of the orientation flat OF is preferably 30% or less of the film thickness Et of the SiC epitaxial film E at the wafer center C. The “portion of the orientation flat OF” means a portion of the outer circumferential portion of the SiC epitaxial film E in which the orientation flat OF is formed.

Even if the epi crown Ec is present in the vicinity of the orientation flat OF of the SiC epitaxial wafer 1, it is possible to take measures such as removing the epi crown Ec only in the vicinity of the orientation flat OF. Therefore, even if the epi crown Ec is present in the vicinity of the orientation flat OF, an effect thereof is small compared to a case in which the epi crown Ec is present in a portion other than the vicinity of the orientation flat OF.

When the height h4 of the epi crown Ec with respect to the level surface of the SiC epitaxial film E measured by the above-described method for arbitrary one location of a portion of the orientation flat OF is 30% or less of the film thickness Et of the SiC epitaxial film E at the wafer center C, the epi crown Ec does not cause any problem when the SiC epitaxial wafer 1 is used to manufacture a product such as a device. Also, the height h4 measured by the above-described method is preferably smaller, more preferably 20% or less of the film thickness Et of the SiC epitaxial film E at the wafer center C, still more preferably 10% or less, yet still more preferably 5% or less, particularly preferably 2% or less, and most preferably 0% or less (no epi crown Ec is formed).

In the present embodiment, as illustrated in FIG. 1A, the SiC epitaxial wafer 1 provided with the orientation flat OF has been described as an example, but the SiC epitaxial wafer 1 of the present embodiment may have a notch formed therein instead of the orientation flat OF.

If the SiC epitaxial wafer 1 is one provided with a notch instead of the orientation flat OF, the height h of the epi crown Ec with respect to the level surface of the SiC epitaxial film E in the SiC epitaxial wafer 1 of the present embodiment means a height h measured by the above-described method for the top surface or apex of the epi crown Ec of the SiC epitaxial film E at a position on a wafer diameter intersecting a groove bottom of the notch (in other words, at a position on the outer circumferential portion of the SiC epitaxial film E on a side opposite to a position at which the groove bottom of the notch is provided with respect to the wafer center).

The height h of the epi crown Ec with respect to the level surface of the SiC epitaxial film E and a dimensional difference in the height h described above due to a circumferential position of the SiC epitaxial film E are unlikely to be affected by whether or not the notch is provided.

Therefore, if the SiC epitaxial wafer 1 is one provided with a notch instead of the orientation flat OF, the height h measured by the above-described method for the top surface or apex of the epi crown Ec of the SiC epitaxial film E at a position on a wafer diameter intersecting the bottom groove of the notch can be taken as the height h of the epi crown Ec with respect to the level surface of the SiC epitaxial film E.

In the SiC epitaxial wafer 1 of the present embodiment, not only the height h at the position on the wafer diameter intersecting the groove bottom of the notch, but also a maximum value h5 of the height of the epi crown Ec with respect to the level surface of the SiC epitaxial film E measured by the above-described method for each of two locations on an upstream side and a downstream side of the step flow in the outer circumferential portion of the SiC epitaxial film E is preferably 30% or less of the film thickness Et of the SiC epitaxial film E at the wafer center C.

Further, in the SiC epitaxial wafer 1, a maximum value h6 of the height of the epi crown Ec with respect to the level surface of the SiC epitaxial film E measured by the above-described method for each of eight locations disposed along the outer circumferential portion at substantially regular intervals including the position on a wafer diameter intersecting the groove bottom of the notch and the two locations on the upstream side and the downstream side of the step flow in the outer circumferential portion of the SiC epitaxial film E is preferably 30% or less of the film thickness Et of the SiC epitaxial film E at the wafer center C.

Even when the notch is formed in the SiC epitaxial wafer 1, similarly to the case in which the orientation flat OF is provided, the height h5 and the height h6 are preferably smaller, more preferably 20% or less of the film thickness Et of the SiC epitaxial film E at the wafer center C, still more preferably 10% or less, yet still more preferably 5% or less, particularly preferably 2% or less, and most preferably 0% or less (no epi crown Ec is formed).

In the present embodiment, a case in which the orientation flat OF or the notch is provided in the SiC epitaxial wafer 1 has been described as an example, but the SiC epitaxial wafer may not have the orientation flat OF and the notch. In this case, the height h of the epi crown Ec with respect to the level surface of the SiC epitaxial film E is a maximum value of the height of the epi crown Ec with respect to the level surface of the SiC epitaxial film E measured by the above-described method for each of two locations on an upstream side and a downstream side of the step flow in the outer circumferential portion of the SiC epitaxial film E. The maximum value of the height is 30% or less of the film thickness Et of the SiC epitaxial film E at the wafer center C.

The SiC epitaxial film E on the SiC epitaxial wafer 1 of the present embodiment has no triangular defects in a region R1 (see FIG. 1A) that is less than 1 mm from an edge 11 in a direction toward the wafer center. Therefore, in the SiC epitaxial wafer 1 of the present embodiment, triangular defects present in the region R1 do not serve as a starting point of cracks, and cracks due to the triangular defects on an outer edge portion of the SiC epitaxial film E are less likely to occur during processing.

In the present embodiment, the “edge 11” means an outer edge of the SiC epitaxial wafer 1 in a plan view.

Further, the SiC epitaxial film E on the SiC epitaxial wafer 1 of the present embodiment preferably does not have triangular defects in a region of 2 mm to 3 mm from the edge 11 in a direction toward the wafer center. This is because the SiC epitaxial wafer 1 can be made small in edge exclusion, and has a small invalid region and a high proportion of effective area usable for products such as devices.

Also, it is more preferable that the SiC epitaxial film E on the SiC epitaxial wafer 1 of the present embodiment do not have triangular defects in a region R3 (see FIG. 1A) that is 3 mm or less from the edge 11 in a direction toward the wafer center. This is because the SiC epitaxial wafer 1 is less likely to crack during processing, can be made small in edge exclusion, and has a high proportion of effective area usable for products such as devices.

In the SiC epitaxial film E on the SiC epitaxial wafer 1 of the present embodiment, a nitrogen concentration at a position 1 mm from the edge 11 in a direction toward the wafer center is preferably 108% or less of a nitrogen concentration at the wafer center C, and more preferably 103% or less. If nitrogen is used as a dopant gas when the SiC epitaxial wafer 1 of the present embodiment is manufactured, a nitrogen concentration (carrier concentration) of the SiC epitaxial film E at the outer circumferential portion tends to be higher than that at the wafer center C. The SiC epitaxial film E, in which the nitrogen concentration at a position 1 mm from the edge 11 in a direction toward the wafer center is 108% or less of the nitrogen concentration at the wafer center C, has a small in-plane variation of the SiC epitaxial film E in nitrogen concentration, and can be suitably used when products such as devices are manufactured.

A size of the SiC epitaxial wafer 1 of the present embodiment is not particularly limited, and may be 150 mm (6 inches) or more in diameter or 200 mm (8 inches) or more in diameter. If the SiC epitaxial wafer 1 of the present embodiment has a large diameter of 150 mm (6 inches) or more, or even 200 mm (8 inches) or more, when it is used as a wafer for semiconductor devices, semiconductor devices can be produced efficiently, and this is preferable. Also, if the SiC epitaxial wafer 1 of the present embodiment has a large diameter, the effect of increasing the proportion of effective area usable for products such as devices is remarkable due to the small edge exclusion, and this is preferable.

### Manufacturing Method of Epitaxial Wafer

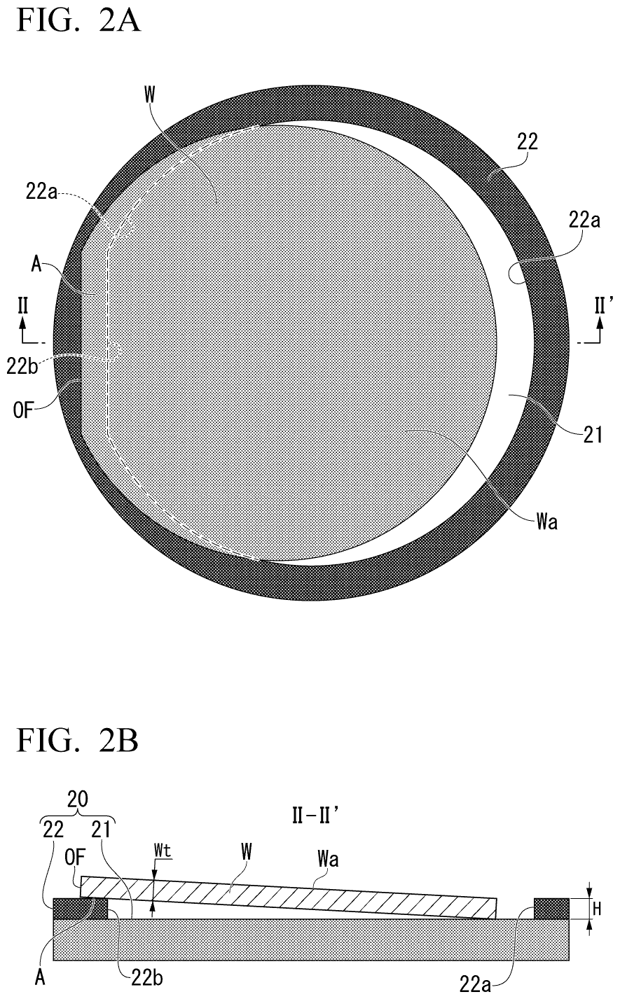

The SiC epitaxial wafer 1 of the present embodiment illustrated in FIGS. 1A and 1B can be manufactured, for example, by a method described below. First, the SiC single crystal substrate W on which the SiC epitaxial film E is laminated is manufactured by a known method. Next, in the manufacturing method of the SiC epitaxial wafer 1 of the present embodiment, the SiC epitaxial film E is grown on the main surface Wa of the SiC single crystal substrate W by a chemical vapor deposition method (film deposition step). FIG. 2A is a plan view for illustrating a film deposition step in the manufacturing method of the SiC epitaxial wafer 1 of the present embodiment, and FIG. 2B is a cross-sectional view taken along line II-II′ in FIG. 2A.

In the film deposition step of the present embodiment, a chemical vapor deposition apparatus is used. As the chemical vapor deposition apparatus, one having, for example, a chamber (film deposition chamber) exhaustible to a low pressure for growing the SiC epitaxial film E on the SiC single crystal substrate W, a wafer support base 20 (susceptor) rotatably supporting the SiC single crystal substrate W around a center axis inside the chamber, a heating unit heating the SiC single crystal substrate W and maintaining it at a predetermined temperature, and a gas supply unit supplying a gas containing a source gas to the SiC single crystal substrate W, is used.

As illustrated in FIGS. 2A and 2B, the wafer support base 20 includes a wafer placement surface 21 on which the SiC single crystal substrate W is placed, and a wafer support part 22 having an annular wall surface 22a that stands upright to surround a circumference of the SiC single crystal substrate W.

The wafer placement surface 21 has a flat plate shape that is substantially circular in a plan view. The wafer support part 22 has an annular shape in a plan view that is substantially concentric with the wafer placement surface 21, and is disposed along an outer edge of the wafer placement surface 21. The wafer placement surface 21 and the wafer support part 22 are rotatable about the center axis with them integrated.

A diameter of the annular wall surface 22a (inner wall surface) of the wafer support part 22 can be, for example, 10 μm to 3000 μm larger than a diameter of the SiC single crystal substrate W, and is preferably 100 μm to 1000 μm larger. When a difference between the diameter of the annular wall surface 22a and the diameter of the SiC single crystal substrate W is 10 μm or more, this is preferable because formation of triangular defects caused by dust generation due to rubbing between a side surface of the SiC single crystal substrate W and the wall surface 22a of the wafer support part 22 can be more effectively prevented. When the difference between the diameter of the annular wall surface 22a and the diameter of the SiC single crystal substrate W is 3000 μm or less, supply of the source gas to the outer circumferential portion of the SiC single crystal substrate W can be effectively hindered. As a result, the growth of the epi crown Ec can be further suppressed.

In the present embodiment, it is preferable that a planar shape of the annular wall surface 22a of the wafer support part 22 be shaped to follow a shape of the orientation flat OF of the SiC single crystal substrate W. Specifically, in the present embodiment, as illustrated in FIG. 2A, a portion of the annular wall surface 22a facing the orientation flat OF of the SiC single crystal substrate W is defined as a flat surface 22b that forms a chord in a circular shape along the annular wall surface 22a in a plan view. The flat surface 22b is formed on an inward side of a substantially circular curved surface along the annular wall surface 22a. A length of the flat surface 22b in a plan view (the length of a chord of a circle along the annular wall surface 22a) corresponds to a length of the orientation flat OF.

In the present embodiment, it is preferable that the flat surface 22b formed on the annular wall surface 22a of the wafer support part 22 and the orientation flat OF of the SiC single crystal substrate W be disposed substantially parallel to each other. Further, in an epitaxial growth step to be described later, the wafer support part 22 of the present embodiment is configured such that, when the entire SiC single crystal substrate W is accommodated inside the annular wall surface 22a of the wafer support part 22, and the flat surface 22b formed on the annular wall surface 22a and the orientation flat OF of the SiC single crystal substrate W are placed parallel to each other, a longest distance between the flat surface 22b and the orientation flat OF is preferably 0.1 mm or more and 0.5 mm or less.

If the above-described longest distance between the flat surface 22b of the wafer support part 22 and the orientation flat OF is 0.1 mm or more, this is preferable because formation of triangular defects caused by dust generation due to rubbing between the side surface of the SiC single crystal substrate W and the wall surface 22a of the wafer support part 22 can be more effectively prevented. Also, if the above-described longest distance between the flat surface 22b and the orientation flat OF is 0.5 mm or less, supply of the source gas to the vicinity of the orientation flat OF of the SiC single crystal substrate W can be effectively hindered. As a result, growth of the epi crown Ec in the vicinity of the orientation flat OF can be further suppressed.

In the present embodiment, as illustrated in FIG. 2A, a portion of the annular wall surface 22a of the wafer support part 22 facing the orientation flat OF of the SiC single crystal substrate W is the flat surface 22b that forms a chord in the circular shape along the annular wall surface 22a in a plan view. Therefore, for example, compared to a case in which the annular wall surface 22a does not have the flat surface 22b and has only a substantially circular curved surface along the annular wall surface 22a, the distance between the annular wall surface 22a and the SiC single crystal substrate W is substantially uniform. As a result, a function of the wall surface 22a to suppress growth of the epi crown Ec by appropriately hindering supply of the source gas to the outer circumferential portion of the SiC single crystal substrate W is effectively exerted over the entire outer circumferential portion of the SiC single crystal substrate W. Therefore, the SiC epitaxial wafer 1, in which the height h of the epi crown Ec with respect to the level surface of the SiC epitaxial film E is suppressed over the entire outer circumferential portion of the SiC single crystal substrate W, can be manufactured.

Also, since a portion of the annular wall surface 22a facing the orientation flat OF is the flat surface 22b that forms a chord in a circular shape along the annular wall surface 22a in a plan view, an area of a region on the wafer placement surface 21 on which the SiC single crystal substrate W is not placed is small compared to, for example, a case in which the annular wall surface 22a does not have the flat surface 22b. Therefore, when the film deposition step to be described later is performed, an amount of deposited materials deposited in the region on the wafer placement surface 21 on which the SiC single crystal substrate W is not placed is reduced. As a result, when the film deposition step to be described later is performed, the SiC single crystal substrate W becomes a floating state with respect to the wafer placement surface 21 due to the deposited materials deposited in the region on the wafer placement surface 21 on which the SiC single crystal substrate W is not placed, and this can prevent a quality of the SiC epitaxial film E from being affected.

In the present embodiment, a height dimension H of the annular wall surface 22a of the wafer support part 22 is made to be larger than a thickness dimension Wt of the SiC single crystal substrate W. Therefore, in the film deposition step, it is possible to prevent the source gas from being excessively supplied to the outer circumferential portion of the SiC single crystal substrate W rotating together with the wafer support base 20. As a result, a growth rate of the SiC epitaxial film E at the outer circumferential portion is suppressed, and growth of the epi crown Ec is suppressed. The height dimension H of the annular wall surface 22a is preferably larger than the thickness dimension Wt of the SiC single crystal substrate W by 1 mm or more, more preferably by 1.5 mm or more, and still more preferably by 2 mm or more. As the height dimension H of the annular wall surface 22a becomes larger than the thickness dimension Wt of the SiC single crystal substrate W, supply of the source gas to the outer circumferential portion of the SiC single crystal substrate W rotating together with the wafer support base 20 can be further hindered, and growth of the epi crown Ec can be more effectively suppressed.

A difference between the height dimension H of the annular wall surface 22a and the thickness dimension Wt of the SiC single crystal substrate W is preferably 5 mm or less, and more preferably 4 mm or less. This is because a flow of the gas supplied to the SiC single crystal substrate W rotating together with the wafer support base 20 can be prevented from being significantly disturbed by the wafer support part 22.

In the present embodiment, the wafer support part 22 of the wafer support base 20 may have a substantially uniform thickness with its upper surface substantially parallel to the wafer placement surface 21 as illustrated in FIG. 2B, or may not have a uniform thickness. As the wafer support part 22 with a non-uniform thickness, for example, one whose upper surface is an inclined surface in which a thickness thereof gradually increases from a center toward the outside in a cross-sectional view can be mentioned.

The wafer placement surface 21 and the wafer support part 22 forming the wafer support base 20 used in the manufacturing method of the present embodiment are preferably made of graphite. The wafer placement surface 21 and the wafer support part 22 may be configured such that only a part of the surface made of graphite may be covered with a coating layer made of TaC or SiC, so that only a part of the surface is made of graphite. If the wafer placement surface 21 and/or the wafer support part 22 is made of graphite and a part of the surface is covered with the coating layer, when locations and areas of the coating layer covering a part of the surface are appropriately adjusted, an amount of carbon supplied from the wafer placement surface 21 and/or the wafer support part 22 as a raw material of the SiC epitaxial film E can be changed in the film deposition step.

In the present embodiment, it is preferable that at least a part of one or both of a surface of the wafer placement surface 21 facing the SiC single crystal substrate W and a surface of the wafer support part 22 be made of graphite. In this case, the carbon derived from the wafer placement surface 21 and/or the wafer support part 22 is supplied as a raw material for the SiC epitaxial film E in the film deposition step. For this reason, for example, when a gas containing nitrogen (N₂) as a dopant gas is supplied by the gas supply unit together with the source gas, the SiC epitaxial wafer 1 with a small in-plane variation of the SiC epitaxial film E in nitrogen concentration can be obtained.

The film deposition step in the present embodiment includes a substrate placement step and an epitaxial growth step.

### Substrate Placement Step

In the substrate placement step, the SiC single crystal substrate W is placed so that the main surface Wa thereof is inclined with respect to the wafer placement surface 21 as illustrated in FIG. 2B, and a part of the SiC single crystal substrate W is disposed outward of the annular wall surface 22a of the wafer support part 22 in a plan view as illustrated in FIGS. 2A and 2B. Therefore, in the manufacturing method of the present embodiment, a region in which a side surface of the SiC single crystal substrate W and the wafer support part 22 are disposed to face each other is small compared to a case in which, for example, the SiC single crystal substrate W is placed in contact with the wafer placement surface 21 inside the annular wall surface 22a of the wafer support part 22.

Therefore, in the epitaxial growth step to be described later, the SiC single crystal substrate W deforms as a temperature of the SiC single crystal substrate W rises, and thereby rubbing between the side surface of the SiC single crystal substrate W and the annular wall surface 22a of the wafer support part 22 can be suppressed. Therefore, triangular defects caused by dust generation due to rubbing between the SiC single crystal substrate W and the wafer support part 22 are less likely to be formed, the SiC epitaxial film E having no triangular defects in the region R1 (see FIG. 1A), that is less than 1 mm from the edge 11 in a direction toward the wafer center, can be obtained, and the SiC epitaxial wafer 1 can be manufactured with a high yield.

In the present embodiment, it is preferable to use the SiC single crystal substrate W provided with the orientation flat OF, and to place the orientation flat OF of the SiC single crystal substrate W on an outward side of the annular wall surface 22a of the wafer support part 22 in the substrate placement step as illustrated in FIGS. 2A and 2B.

In this case, in the epitaxial growth step to be described later, when the entire SiC single crystal substrate W is accommodated inside the annular wall surface 22a of the wafer support part 22, among an outer surface of the SiC single crystal substrate W rubbing against the wafer support part 22, an area of the outer surface other than the orientation flat OF can be reduced. Also, movement of the SiC single crystal substrate W on the wafer placement surface 21 during growth of the SiC epitaxial film E is suppressed by the wafer support part 22. As a result, an amount of dust generated by rubbing between the SiC single crystal substrate W and the wafer support part 22 and/or the wafer placement surface 21 is suppressed, and triangular defects caused by the dust generation are less likely to be formed. Therefore, the SiC epitaxial film E having no triangular defects in the region R1, that is less than 1 mm from the edge 11 in a direction toward the wafer center, and having no triangular defects even in the region of 2 mm to 3 mm can be obtained.

In the present embodiment, it is preferable that an area A of a surface of the SiC single crystal substrate W on a side opposite to the main surface Wa, which is placed outward of the annular wall surface 22a of the wafer support part 22 in a plan view, be 0.01% to 10% of an area of the SiC single crystal substrate W. If the above-described area A is 0.01% or more of the area of the SiC single crystal substrate W, the SiC single crystal substrate W can be stably placed so that the main surface Wa thereof is inclined with respect to the wafer placement surface 21 in the substrate placement step. Also, if the above-described area A is 0.01% or more of the area of the SiC single crystal substrate W, in the epitaxial growth step to be described later, even if the SiC single crystal substrate W bends and deforms into a convex shape or a concave shape due to a thermal stress caused by growing the SiC epitaxial film E, the SiC single crystal substrate W and the wafer support part 22 do not rub against each other. Therefore, if the above-described area A is 0.01% to 10% of the area of the SiC single crystal substrate W, the SiC epitaxial film E having no triangular defects in the region R3 (see FIG. 1A), that is 3 mm or less from the edge 11 in a direction toward the wafer center, can be obtained.

Also, if the above-described area A is 10% or less of the area of the SiC single crystal substrate W, in the epitaxial growth step to be described later, the entire SiC single crystal substrate W can be easily and reliably accommodated inside the annular wall surface 22a of the wafer support part 22 before a temperature of the SiC single crystal substrate W reaches an epitaxial growth temperature by rotating the wafer support base 20 while raising the temperature of the SiC single crystal substrate W.

If the SiC single crystal substrate W with a notch formed instead of the orientation flat OF is used as the SiC single crystal substrate W, or if the SiC single crystal substrate W without the orientation flat OF or the notch is used as the SiC single crystal substrate W, it is preferable that the area A of a surface of the SiC single crystal substrate W on a side opposite to the main surface Wa, which is placed outward of the annular wall surface 22a of the wafer support part 22 in a plan view, be 0.01% to 3% of the area of the SiC single crystal substrate W.

If the above-described area A is 0.01% or more of the area of the SiC single crystal substrate W, the SiC single crystal substrate W can be stably placed so that the main surface Wa thereof is inclined with respect to the wafer placement surface 21 in the substrate placement step. Also, if the above-described area A is 3% or less of the area of the SiC single crystal substrate W, in the epitaxial growth step to be described later, the entire SiC single crystal substrate W can be easily and reliably accommodated inside the annular wall surface 22a of the wafer support part 22 before a temperature of the SiC single crystal substrate W reaches the epitaxial growth temperature by rotating the wafer support base 20 while raising the temperature of the SiC single crystal substrate W.

Also, in the present embodiment, in the film deposition step, the wafer support base 20 in which the height dimension H of the annular wall surface 22a of the wafer support part 22 is larger than the thickness dimension Wt of the SiC single crystal substrate W is used. Therefore, in the epitaxial growth step to be described later, it is possible to prevent the source gas from being excessively supplied to the outer circumferential portion of the SiC single crystal substrate W rotating together with the wafer support base 20. As a result, the SiC epitaxial wafer 1 in which the height h of the epi crown Ec with respect to the level surface of the SiC epitaxial film E is 30% or less of the film thickness Et of the SiC epitaxial film E at the wafer center C is obtained.

### Epitaxial Growth Step

In the epitaxial growth step, the entire SiC single crystal substrate W is accommodated inside the annular wall surface 22a of the wafer support part 22 before a temperature of the SiC single crystal substrate W reaches the epitaxial growth temperature by rotating the wafer support base 20 while raising the temperature of the SiC single crystal substrate W with the heating unit. Then, a gas containing the source gas is supplied at a predetermined flow rate by the gas supply unit onto the SiC single crystal substrate W from the outside of an outer circumferential end portion of the SiC single crystal substrate W rotating at a predetermined rotation speed together with the wafer support base 20.

In the epitaxial growth step, when the wafer support base 20 is rotated while raising a temperature of the SiC single crystal substrate W with the heating unit, the SiC single crystal substrate W, while being deformed by heat, is guided and moved by the annular wall surface 22a of the wafer support part 22 due to a wind pressure on the side surface of the SiC single crystal substrate W caused by the rotation of the wafer support base 20. As a result, the entire SiC single crystal substrate W is accommodated inside the annular wall surface 22a of the wafer support part 22 before a temperature of the SiC single crystal substrate W reaches the epitaxial growth temperature.

In the present embodiment, if the wafer support part 22 of the wafer support base 20 whose upper surface is an inclined surface, in which a thickness thereof gradually increases from the center toward the outside in a cross-sectional view, is used, in the epitaxial growth step, the SiC single crystal substrate W is quickly and reliably moved to the inside of the wafer support part 22 by rotating the wafer support base 20 while raising the temperature of the SiC single crystal substrate W. As a result, the entire SiC single crystal substrate W is more easily and more reliably accommodated inside the annular wall surface 22a of the wafer support part 22 before the temperature of the SiC single crystal substrate W reaches the epitaxial growth temperature.

Particularly, if the SiC single crystal substrate W with a notch formed instead of the orientation flat OF is used as the SiC single crystal substrate W, or if the SiC single crystal substrate W without the orientation flat OF or the notch is used as the SiC single crystal substrate W, it is preferable to use the wafer support part 22 of the wafer support base 20 whose upper surface is an inclined surface in which a thickness thereof gradually increases from the center toward the outside in a cross-sectional view.

In the epitaxial growth step, the SiC epitaxial film E is grown on the SiC single crystal substrate W until it reaches a predetermined thickness while the SiC single crystal substrate W is heated by the heating unit and maintained at a predetermined temperature. Conditions in the epitaxial growth step such as a temperature of the SiC single crystal substrate W, a rotation speed of the SiC single crystal substrate W, and a flow rate of each gas in the gas containing the source gas can be known conditions and can be appropriately determined according to a size of the SiC single crystal substrate W, a film deposition rate, or the like.

In the epitaxial growth step of the present embodiment, a Si atom-containing gas and a C atom-containing gas are used as the source gas. As the source gas, a dopant gas may be used together with the Si atom-containing gas and the C atom-containing gas. Also, a carrier gas may be used together with the source gas.

As the Si atom-containing gas, for example, silane (SiH₄), dichlorosilane (SiCl₂H₂), trichlorosilane (SiCl₃), silicon tetrachloride (SiCl₄), or the like can be used. As the C atom-containing gas, for example, propane (C₃H₈), ethane (C₂H₆), ethylene (C₂H₄), or the like can be used. As the dopant gas, for example, nitrogen (N₂) or the like can be used. As the carrier gas, for example, a gas containing hydrogen (H₂) can be used.

The Si atom-containing gas, the C atom-containing gas, the dopant gas, and the carrier gas can each be used alone or in combination of two or more, and these can be appropriately determined according to an application of the SiC epitaxial wafer 1. Each gas contained in the gas including the source gas used in the epitaxial growth step may be supplied individually by the gas supply unit, or may be supplied in a state of a mixed gas obtained by mixing one or more gases in a predetermined ratio. Specifically, for example, the Si atom-containing gas and the C atom-containing gas may be mixed in a predetermined ratio to form a mixed gas, which may be supplied as the source gas.

Also, in the epitaxial growth step of the present embodiment, a source gas including silane (SiH₄) serving as the Si atom-containing gas and propane (C₃H₈) serving as the C atom-containing gas, and a gas containing nitrogen (N₂) serving as the dopant gas may be supplied by the gas supply unit. In this case, as will be described below, the in-plane variation of the SiC epitaxial film E in nitrogen concentration tends to be large.

A decomposition rate of propane (C₃H₈) is lower than that of silane (SiH₄). Therefore, decomposition of the propane supplied from the outside of the outer circumferential end portion of the SiC single crystal substrate W has not yet sufficiently progressed by the time the propane reaches the vicinity of the outer circumferential portion of the SiC single crystal substrate W. On the other hand, decomposition of the propane supplied from the outside of the outer circumferential end portion of the SiC single crystal substrate W has progressed sufficiently by the time the propane reaches the vicinity of the wafer center C of the SiC single crystal substrate W. Therefore, the SiC epitaxial film E grown in the vicinity of the outer circumferential portion of the SiC single crystal substrate W tends to have a smaller amount of carbon atoms compared to the SiC epitaxial film E grown in the vicinity of the wafer center C of the SiC single crystal substrate W.

As a result, a C/Si ratio of the SiC epitaxial film E is relatively low at the outer circumferential portion, making it easier for nitrogen atoms to enter sites occupied by carbon atoms. Therefore, an amount of nitrogen atoms taken into the SiC epitaxial film E at the outer circumferential portion increases, and a carrier concentration at the outer circumferential portion of the SiC epitaxial film E increases, resulting in larger in-plane variation.

Therefore, in the present embodiment, if a source gas including silane (SiH₄) serving as the Si atom-containing gas and propane (C₃H₈) serving as the C atom-containing gas, and a gas containing nitrogen (N₂) serving as the dopant gas are used, it is preferable to use the wafer support base 20 in which at least a part of one or both of a surface of the wafer placement surface 21 facing the SiC single crystal substrate W and a surface of the wafer support part 22 is made of graphite.

In this case, in the epitaxial growth step, carbon derived from the wafer placement surface 21 and/or the wafer support part 22, together with propane supplied from the outside of the outer circumferential end portion of the SiC single crystal substrate W, is used as a raw material for the SiC epitaxial film E. Therefore, even if decomposition of propane has not progressed sufficiently by the time the propane reaches the vicinity of the outer circumferential portion of the SiC single crystal substrate W, the C/Si ratio in the SiC epitaxial film E grown in the vicinity of the outer circumferential portion of the SiC single crystal substrate W is less likely to become low. Therefore, nitrogen atoms are prevented from being excessively taken into the SiC epitaxial film E at the outer circumferential portion, and the SiC epitaxial film E with a small in-plane variation in nitrogen concentration is grown. As a result, the SiC epitaxial film E, in which the nitrogen concentration at a position 1 mm from the edge 11 of the SiC epitaxial wafer 1 in a direction toward the wafer center is 108% or less of the nitrogen concentration at the wafer center C, is obtained.

Although the preferred embodiment of the present invention has been described in detail above, the present invention is not limited to the specific embodiment, and various modifications and changes can be made within the range of the gist of the present invention described in the claims.

For example, in the embodiment described above, a case in which the single crystal substrate is a SiC single crystal substrate and the epitaxial film is a SiC epitaxial film has been described as an example of the epitaxial wafer of the present invention, but a material of the single crystal substrate is not particularly limited, and the epitaxial film may be, for example, Si, a III-V group compound, or the like.

### EXAMPLE

Hereinafter, the present invention will be described more specifically with reference to an example and comparative examples. Further, the present invention is not limited only to the following example.

### Example 1

As a chemical vapor deposition apparatus, one having a chamber (film deposition chamber) exhaustible to a low pressure for growing the SiC epitaxial film E on the SiC single crystal substrate W, the wafer support base 20 (susceptor) rotatably supporting the SiC single crystal substrate W around a center axis inside the chamber, a heating unit heating the SiC single crystal substrate W and maintaining it at a predetermined temperature, and a gas supply unit supplying a gas containing a source gas to the SiC single crystal substrate W, was prepared.

As the wafer support base 20, one having the wafer placement surface 21 and the wafer support part 22 illustrated in FIGS. 2A and 2B was used. As the wafer placement surface 21 and the wafer support part 22, those made of graphite were used. As the wafer placement surface 21, one having a diameter of 180 mm was used. The wafer support part 22, in which the height dimension H of the annular wall surface 22a was 1.5 mm, a diameter of the annular wall surface 22a was 10 μm to 3000 μm larger than a diameter of the SiC single crystal substrate W, and when the SiC single crystal substrate W was accommodated inside the annular wall surface 22a of the wafer support part 22, and the flat surface 22b formed on the annular wall surface 22a and the orientation flat OF of the SiC single crystal substrate W were placed parallel to each other, a longest distance therebetween was 0.1 mm or more and 0.5 mm or less, was used.

Then, the SiC single crystal substrate W was placed so that the main surface Wa thereof was inclined with respect to the wafer placement surface 21 as illustrated in FIG. 2B. At this time, the orientation flat OF of the SiC single crystal substrate W was placed outward of the annular wall surface 22a of the wafer support part 22. Also, the SiC single crystal substrate W was placed so that the area A of a surface of the SiC single crystal substrate W on a side opposite to the main surface Wa, which was placed outward of the annular wall surface 22a of the wafer support part 22, was 1% of the area of the SiC single crystal substrate W (substrate placement step).

Thereafter, the wafer support base 20 was rotated at a rotation speed of 10 rpm to 1000 rpm while raising a temperature of the SiC single crystal substrate with the heating unit. Thereby, the entire SiC single crystal substrate W was accommodated inside the annular wall surface 22a of the wafer support part 22 before the temperature of the SiC single crystal substrate W reached a predetermined temperature of 1400° C. or higher which was an epitaxial growth temperature. Then, the SiC single crystal substrate W was heated to the epitaxial growth temperature by the heating unit, a gas containing the source gas was supplied onto the SiC single crystal substrate W from the outside of the outer circumferential end portion of the SiC single crystal substrate W rotating together with the wafer support base 20 by the gas supply unit while maintaining the temperature, and the SiC epitaxial film E was grown on the SiC single crystal substrate W so that the film thickness Et of the SiC epitaxial film E at the wafer center C was 10 to 100 μm (epitaxial growth step). As a result, the SiC epitaxial wafer 1 of example 1 was obtained.

In Example 1, as the SiC single crystal substrate W, one with a thickness of 350 μm and a diameter of 150 mm (6 inches), and having the orientation flat OF, was used.

Also, as the source gas, a mixed gas consisting of a Si atom-containing gas made of silane (SiH₄) and a C atom-containing gas made of propane (C₃H₈) was used. Then, the source gas, a dopant gas made of nitrogen (N₂), and a carrier gas made of hydrogen (H₂) were mixed to be supplied to the SiC single crystal substrate W.

For the SiC epitaxial wafer 1 of example 1, the film thickness Et of the SiC epitaxial film E and the height h of the epi crown Ec with respect to the level surface of the SiC epitaxial film E were measured using a cross-sectional image of the SiC epitaxial film E captured using a scanning electron microscope (SEM). The height h was measured at a position on a wafer diameter intersecting a longitudinal center of the orientation flat OF (in other words, at a position on the outer circumferential portion of the SiC epitaxial film E on a side opposite to a position at which the longitudinal center of the orientation flat OF is provided with respect to the wafer center), and a ratio of the height h to the film thickness Et of the SiC epitaxial film E at the wafer center C ((height h/film thickness Et)×100 (%)) was determined. The result is shown in Table 1.

Also, for the SiC epitaxial wafer 1 of example 1, the number of triangular defects was measured in a region less than 1 mm from the edge 11 of the SiC epitaxial film E in a direction toward the wafer center and in a region of 3 mm or less using the method described below.

As a result, as shown in Table 1, there were no triangular defects in the region 3 mm or less from the edge in a direction toward the wafer center.

### Method of Measuring Number of Triangular Defects

An image obtained by microscopic observation of a surface of the SiC epitaxial wafer using a SiC wafer defect inspection device (SICA88 (manufactured by Lasertec Corporation)) was visually observed to examine the number of triangular defects.

Also, for the SiC epitaxial wafer 1 of example 1, a nitrogen concentration at a position 1 mm from the edge 11 of the SiC epitaxial film E in a direction toward the wafer center and a nitrogen concentration at the wafer center C were measured using a mercury probe (Hg-CV) method. Then, a ratio of the nitrogen concentration at the position 1 mm from the edge 11 in a direction toward the wafer center to the nitrogen concentration at the wafer center C ((1 mm from edge/wafer center)×100 (%)) was determined. The result is shown in Table 1.

TABLE 1

| | | Triangular | Triangular | |
|---|---|---|---|---|
| | Ratio | defects in | defects in | Ratio of |
| | of | region | region | nitrogen |
| | height | less than | 3 mm or | concentration |
| | h (%) | 1 mm (piece) | less (piece) | (%) |
| Example 1 | 0 | 0 | 0 | 105 |
| Comparative | 0 | 5 | 22 | — |
| example 1 | | | | |
| Comparative | — | 6 | 19 | — |
| example 2 | | | | |

### Comparative Example 1

A SiC epitaxial wafer of comparative example 1 was obtained in the same manner as in example 1 except that the SiC single crystal substrate W was placed in contact with the wafer placement surface 21 inside the annular wall surface 22a of the wafer support part 22.

### Comparative Example 2

A SiC epitaxial wafer of comparative example 2 was obtained in the same manner as in example 1 except that the wafer support base 20 formed only of the wafer placement surface 21 without the wafer support part 22 was used, and the SiC single crystal substrate W was placed in contact with the wafer placement surface 21.

For the SiC epitaxial wafer of comparative example 1, the film thickness Et of the SiC epitaxial film E and the height h of the epi crown Ec with respect to the level surface of the SiC epitaxial film E were examined in the same manner as in example 1. Also, in the same manner as in example 1, the above-described ratio of the height h to the film thickness Et of the SiC epitaxial film E at the wafer center C ((height h/film thickness Et)×100 (%)) was determined. The result is shown in Table 1.

Also, for the SiC epitaxial wafers of comparative example 1 and comparative example 2, the number of triangular defects was measured in a region less than 1 mm from the edge 11 of the SiC epitaxial film E in a direction toward the wafer center and in a region of 3 mm or less in the same manner as in example 1. The result is shown in Table 1.

As shown in Table 1, in comparative example 1, 22 triangular defects were present in the region 3 mm or less from the edge in a direction toward the wafer center. Also, five triangular defects were present in the region less than 1 mm from the edge in a direction toward the wafer center. This is presumably because, in comparative example 1, as the temperature of the SiC single crystal substrate W increases in the epitaxial growth step, the SiC single crystal substrate W deforms, and a side surface of the SiC single crystal substrate W and the annular wall surface 22a of the wafer support part 22 rub against each other, resulting in generation of dust.

Also, as shown in Table 1, in comparative example 2, 19 triangular defects were present in the region 3 mm or less from the edge in a direction toward the wafer center. Also, six triangular defects were present in the region less than 1 mm from the edge in a direction toward the wafer center. This is presumably because, in comparative example 2, in the step of growing the SiC epitaxial film E, the SiC single crystal substrate W moves on the wafer placement surface 21, and the SiC single crystal substrate W and the wafer placement surface 21 rub against each other, resulting in generation of dust.

### EXPLANATION OF REFERENCES

1 SiC epitaxial wafer
11 Edge
20 Wafer support base
21 Wafer placement surface
22 Wafer support part
22a Wall surface
C Wafer center
E SiC epitaxial film
Ec Epi crown
Ef Flat portion
OF Orientation flat
W SiC single crystal substrate
Wa Main surface

What is claimed is:

1. A SiC epitaxial wafer, which has a SiC single crystal substrate and a SiC epitaxial film on a main surface of the SiC single crystal substrate,
wherein an orientation flat or a notch is provided thereon,
a height of an epi crown, which is present on an outer circumferential portion of the SiC epitaxial film, with respect to a level surface of the SiC epitaxial film is 30% or less of a thickness of the SiC epitaxial film at a wafer center, the epi crown and the wafer center being at a position on a wafer diameter intersecting a longitudinal center of the orientation flat or a groove bottom of the notch, and
the SiC epitaxial film does not have triangular defects in a region less than 1 mm from an edge in a direction toward the wafer center.

2. The SiC epitaxial wafer according to claim 1,
wherein the SiC epitaxial film does not have triangular defects in a region of 2 mm to 3 mm from the edge in a direction toward the wafer center.

3. The SiC epitaxial wafer according to claim 1,
wherein the SiC epitaxial film does not have triangular defects in a region 3 mm or less from the edge in a direction toward the wafer center.

4. The SiC epitaxial wafer according to claim 1,
wherein a nitrogen concentration of the SiC epitaxial film at a position 1 mm from the edge in a direction toward the wafer center is 108% or less of a nitrogen concentration thereof at the wafer center.

5. A manufacturing method of a SiC epitaxial wafer by which a SiC epitaxial film is grown on a main surface of a SiC single crystal substrate, comprising:
a film deposition step of growing the SiC epitaxial film by a chemical vapor deposition method using a chemical vapor deposition apparatus which includes a wafer support base,
the wafer support base having a wafer placement surface on which the SiC single crystal substrate is placed, and a wafer support part,
the wafer support part having an annular wall surface standing upright to surround a circumference of the SiC single crystal substrate, and
the height dimension of the annular wall surface is larger than a thickness dimension of the SiC single crystal substrate,
wherein the film deposition step includes:
a substrate placement step in which the SiC single crystal substrate is placed so that the main surface thereof is inclined with respect to the wafer placement surface, and a part of the SiC single crystal substrate is disposed outward of the annular wall surface of the wafer support part in a plan view; and
an epitaxial growth step in which the entirety of the SiC single crystal substrate is accommodated inside the annular wall surface of the wafer support part before a temperature of the SiC single crystal substrate reaches an epitaxial growth temperature by rotating the wafer support base while raising the temperature of the SiC single crystal substrate, and a gas containing a source gas is supplied onto the SiC single crystal substrate from the outside of an outer circumferential end portion of the SiC single crystal substrate.

6. The manufacturing method of a SiC epitaxial wafer according to claim 5,
wherein an orientation flat of the SiC single crystal substrate is placed outward of the annular wall surface of the wafer support part.

7. The manufacturing method of a SiC epitaxial wafer according to claim 5,
wherein an area of a surface of the SiC single crystal substrate on a side opposite to the main surface, which is placed outward of the annular wall surface of the wafer support part in a plan view, is 0.01% to 10% of an area of the SiC single crystal substrate.

8. The manufacturing method of a SiC epitaxial wafer according to claim 5,
wherein the wafer support base in which at least a part of one or both of a surface of the wafer placement surface facing the SiC single crystal substrate and a surface of the wafer support part is made of graphite is used, and
a nitrogen-containing gas, together with a source gas containing silane and propane, is supplied onto the SiC single crystal substrate.
